(19) United States
(12) Patent Application Publication
(10) Pub. No.: US 2013/0015468 A1
(43) Pub. Date: Jan. 17, 2013

(54) SEMICONDUCTOR DEVICE AND METHOD OF MANUFACTURING THE SAME

(71) Applicant: Masao KIKUCHI, Tokyo (JP)

(72) Inventor: Masao KIKUCHI, Tokyo (JP)

(73) Assignee: Mitsubishi Electric Corporation, Chiyoda-ku (JP)

(21) Appl. No.: 13/405,720

(22) Filed: Feb. 27, 2012

(30) Foreign Application Priority Data
Jul. 14, 2011 (JP) 2011-155525

(51) Int. Cl. H01L 29/16; H01L 21/56

(52) U.S. Cl. 257/77; 438/124; 257/E29.082; 257/E21.502

(57) ABSTRACT

A semiconductor device of the present invention comprises a semiconductor element, a first metal body formed on a back surface of the semiconductor element, a first insulating layer formed on a back surface of the first metal body, a second metal body formed on a back surface of the first insulating layer, a third metal body formed on a front surface of the semiconductor element, a second insulating layer formed on a front surface of the third metal body and a fourth metal body formed on a front surface of the second insulating layer, and the second metal body is thinner than the first metal body and the fourth metal body is thicker than the third metal body. With this structure, it is possible to increase the heat radiation performance while suppressing stress to be exerted on the semiconductor element.

### BACKGROUND OF THE INVENTION

1. Field of the Invention

The present invention relates to a semiconductor device and a method of manufacturing the same, and more particularly to a power semiconductor device which incorporates one or a plurality of power semiconductor elements such as MOSFET(s), IGBT(s), or the like and controls the load of a motor or the like.

2. Description of the Background Art

Semiconductor elements, or particularly power semiconductor elements, in a semiconductor device control a large load of a motor or the like. For this reason, a power semiconductor element controls a large amount of current and generates a large amount of heat by itself. Therefore, the power semiconductor device accommodating the power semiconductor element(s) is especially required to ensure sufficient thermal radiation.

A background-art power semiconductor element is mounted on an insulating substrate, and the insulating substrate is bonded onto a metal plate and further accommodated in a case. Respective one ends of a plurality of bonding wires are connected to an upper surface electrode of the power semiconductor element and the other ends of the bonding wires are connected to wires on the insulating substrate or electrodes attached onto the case accommodating the insulating substrate. On the other hand, a back surface electrode of the power semiconductor element is bonded to the wires on the insulating substrate with solder.

The power semiconductor device is attached to a cooler with grease interposed between a surface of the metal plate thereof and the cooler, and the heat generated in the power semiconductor element is radiated by the cooler through the solder, the insulating substrate, the metal plate and the like.

Further, in order to supply a voltage to operate the power semiconductor element, a control electrode is provided in the same plane as the upper surface electrode of the power semiconductor element and the control electrode is connected to the wires on the substrate or the electrodes attached to the case with the bonding wires as discussed above. The wires or electrodes in which a large amount of current flows and the controlling wires or electrodes are provided on the same substrate surface or the same case surface in many cases.

The power semiconductor element, such as a MOSFET or an IGBT, is frequently used to control a large amount of current, and some of power semiconductor devices can control a current of about several to several hundreds A. For this reason, in order to increase the cooling performance of the power semiconductor device, for example, such a power semiconductor device as shown in Japanese Patent Application Laid Open Gazette No. 10-56131 is disclosed.

The power semiconductor device shown in Japanese Patent Application Laid Open Gazette No. 10-56131 comprises a plurality of semiconductor elements each having a collector electrode and an emitter electrode formed in the same plane as a control electrode, and further comprises high thermal conductivity insulating substrates which are so formed as to sandwich these semiconductor elements and provided with electrode patterns to be joined to electrodes of the semiconductor chips, on the surfaces thereof which sandwich the semiconductor elements. The electrode patterns of the high thermal conductivity insulating substrates and the electrodes of the semiconductor elements are bonded to each other by brazing.

Since the insulating substrates are so formed as to sandwich the front and back sides of the semiconductor elements in the background-art semiconductor device, however, there arises a problem that the parallelism of the front surfaces of the insulating substrates may be deteriorated depending on the variation in the assembly. Especially in a case where the insulating substrate is formed of ceramics such as aluminum nitride (AlN) or the like in the power semiconductor device disclosed in Japanese Patent Application Laid Open Gazette No. 10-56131, since the insulating substrate is very rigid, there occurs a partial contact in attaching the cooler to the front surface of the insulating substrate in some cases. Then, since there occurs a large gap between the cooler and the insulating substrate, a grease layer becomes thicker and the heat radiation performance is deteriorated.

Further, since excessive force is exerted on the rigid and brittle insulating substrate and a local portion of the semiconductor element, there is a possibility that the insulating substrate and the semiconductor element may be broken.

### SUMMARY OF THE INVENTION

It is an object of the present invention to provide a semiconductor device which is capable of increasing the heat radiation performance while suppressing stress to be exerted on a semiconductor element, and a method of manufacturing the same.

The present invention is intended for a semiconductor device. According to the present invention, the semiconductor device includes a semiconductor element, a first metal body formed on a back surface of the semiconductor element, a first insulating layer formed on a back surface of the first metal body, a second metal body formed on a back surface of the first insulating layer, a third metal body formed on a front surface of the semiconductor element, a second insulating layer formed on a front surface of the third metal body, and a fourth metal body formed on a front surface of the second insulating layer. In the semiconductor device of the present invention, the second metal body is thinner than the first metal body, and the fourth metal body is thicker than the third metal body.

In the semiconductor device of the present invention, the thin third metal body is provided on the front surface side of the semiconductor element, to thereby suppress the stress to be exerted on the semiconductor element and the thick first metal body is provided on the back surface side of the semiconductor element, to thereby achieve low thermal resistance and increase the thermal radiation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross section showing a semiconductor device in accordance with a first preferred embodiment of the present invention;

FIGS. 2 and 3 are schematic cross sections each showing a variation of the semiconductor device in accordance with the first preferred embodiment;

FIGS. 4A to 4C show a flowchart of manufacturing the semiconductor device in accordance with the first preferred embodiment; and

FIG. 5 is a plan view showing the semiconductor device in accordance with the first preferred embodiment.

### DESCRIPTION OF THE PREFERRED EMBODIMENTS

### A. The First Preferred Embodiment

<A-1. Structure>

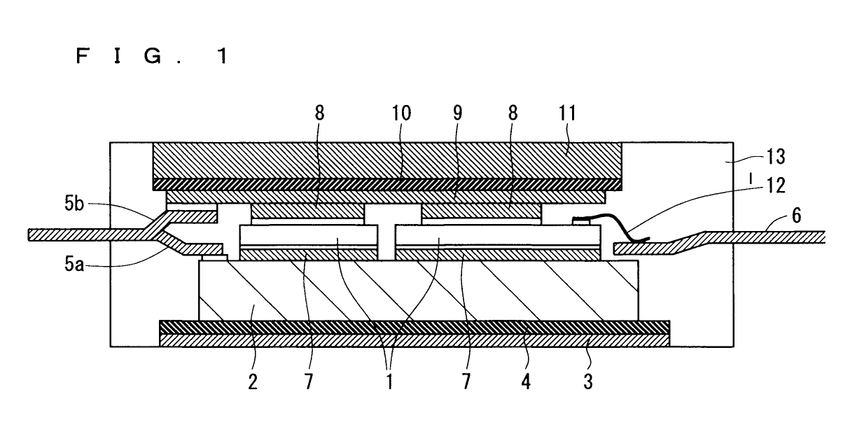

FIG. 1 is a schematic cross section showing a semiconductor device, for explanation of a first preferred embodiment of the present invention.

As shown in FIG. 1, the semiconductor device of the present invention comprises a semiconductor element 1 having a device structure on a front surface thereof, a first metal body 2 connected to a lower direction, i.e., a back surface side of the semiconductor element 1 with a solder 7 interposed therebetween, a first insulating layer 4 formed in a lower direction of the first metal body 2, a second metal body 3 formed in a lower direction of the first insulating layer 4, a third metal body 9 connected to an upper direction, i.e., a front surface side of the semiconductor element 1 with a solder 8 interposed therebetween, a second insulating layer 10 formed in an upper direction of the third metal body 9, and a fourth metal body 11 formed in an upper direction of the second insulating layer 10. Herein, the semiconductor element 1 may be formed mainly of silicon carbide. In the case where the semiconductor element 1 is formed mainly of silicon carbide, the cooling performance increases, and it is thereby possible to achieve a semiconductor device having a synergistically high breakdown voltage.

As shown in FIG. 1, the second metal body 3 is so formed as to be thinner than the first metal body 2 in a vertical direction. The fourth metal body 11 is so formed as to be thicker than the third metal body 9 in the vertical direction.

Further, main terminals 5a and 5b are connected to the first metal body 2 and the third metal body 9, respectively, and the semiconductor element 1 is connected to a signal terminal 6 with a bonding wire 12. The main terminals 5a and 5b may be members which are united with the first metal body 2 and the third metal body 9, respectively, in advance, and in such a case, a connecting process can be omitted.

Input/output electrodes may be formed on the front surface side of the semiconductor element 1 so as to be driven with the semiconductor element 1 or make sensing. These electrodes are connected to the signal terminal 6 with the bonding wires 12.

Further, the whole of the structure may be covered with a mold resin 13, and in such a case, a surface of the second metal body 3 in the lower direction and a surface of the fourth metal body 11 in the upper direction are exposed from the mold resin 13.

The first metal body 2 is formed on the back surface side (in the lower direction) of the semiconductor element 1 with a junction layer such as a solder or the like (the solder 7 in FIG. 1) interposed therebetween. The first insulating layer 4 is provided in the lower direction of the first metal body 2, in other words, on the surface of the first metal body 2 on the opposite side of the semiconductor element 1, and the second metal body 3 is further provided in the lower direction of the first insulating layer 4.

In the back surface side of the semiconductor element 1, since the thick first metal body 2 is formed immediately below the semiconductor element 1, it is possible to sufficiently diffuse the heat and thereby ensure the thermal radiation. The first metal body 2 has only to be sufficiently thicker than the second metal body 3. Further, by providing the first metal body 2 having an area in a horizontal direction which is larger than that of the semiconductor element 1, the diffusion of the heat increases and it is thereby possible to increase the thermal radiation (reduce the thermal resistance).

The second metal body 3 formed in the lower direction of the first insulating layer 4 is provided to protect the first insulating layer 4 and may be thin only if it can sufficiently protect the first insulating layer 4. The thinner the second metal body 3 is, the more preferable it is since the thermal resistance can be reduced. Specifically, it is desirable that the thickness of the second metal body 3 should be, for example, about 0.01 to 0.5 mm.

If a thin metal body is formed immediately below the semiconductor element 1, an insulating layer formed immediately below the thin metal body is provided near the semiconductor element 1 though mechanical stress to be exerted on the semiconductor element 1 can be reduced as discussed later. In such a structure, the heat generated in the semiconductor element 1 reaches the insulating layer before the heat is sufficiently diffused, and the thermal radiation is thereby deteriorated. Therefore, in the first preferred embodiment, the thick metal body (first metal body 2) is provided immediately below the semiconductor element 1.

On the other hand, on the front surface side (in the upper direction) of the semiconductor element 1, which has the device structure, the third metal body 9 is provided with a junction layer such as a solder or the like (the solder 8 in FIG. 1) interposed therebetween, like on the back surface side. The second insulating layer 10 is provided in the upper direction of the third metal body 9, in other words, on the surface of the third metal body 9 on the opposite side of the semiconductor element 1, and the fourth metal body 11 is further provided in the upper direction of the second insulating layer 10.

In the front surface side of the semiconductor element 1, since the thin third metal body 9 is formed immediately above the semiconductor element 1, it is possible to reduce the mechanical stress to be exerted on the device structure including a layer serving as a semiconductor such as a channel portion, a gate electrode, and the like and thereby increase the reliability of the device. The third metal body 9 has only to be sufficiently thinner than the fourth metal body 11, and specifically, it is desirable that the thickness of the third metal body 9 should be, for example, about 0.1 to 1.5 mm.

If a metal body having the same thickness as that of the first metal body 2 is formed immediately above the semiconductor element 1, mechanical stress is exerted on the device structure which is stereoscopically formed on an active surface of the semiconductor element 1 and there is a possibility that the characteristics of the device may be thereby deteriorated. Therefore, in the first preferred embodiment, the thin metal body (third metal body 9) is provided immediately above the semiconductor element 1.

Further, a joinable area on the front surface side of the semiconductor element 1 is smaller than that on the back surface side of the semiconductor element 1 since a signal electrode and the like are provided on the front surface side and a region for ensuring the breakdown voltage is provided in the periphery thereof. Therefore, an area of the third metal body 9 needs to be small in the horizontal direction. By providing the third metal body 9 having a small area in the horizontal direction, it is possible to reduce the mechanical stress.

Further, by providing the second insulating layer 10 immediately above the third metal body 9, it is possible to reduce the mechanical stress to be exerted on a radiation path on an upper surface of the third metal body 9 and achieve high thermal radiation.

Since the second insulating layer 10 has low strength, it is preferable that the second insulating layer 10 which cannot be held by a mold should be held by the fourth metal body 11 in advance. By molding the structure in the state where the second insulating layer 10 is held by the fourth metal body 11, it is possible to increase the strength of the second insulating layer 10 and thereby achieve a double-sided insulating structure having insulating layers with excellent insulation properties.

With the third metal body 9 added thereto, a laminate substrate in which the third metal body 9, the second insulating layer 10, and the fourth metal body 11 are united together in advance by pressing or the like may be used. By forming the laminate substrate in this manner, it is possible to further increase the strength and thereby achieve the double-sided insulating structure having insulating layers with excellent insulation properties.

Further, the third metal body 9, the second insulating layer 10, and the fourth metal body 11 may form a circuit board. By forming the circuit board in this manner, it becomes easier to supply it in molding, and it is thereby possible to reliably ensure the adhesion between the insulating layer and the metal bodies.

Herein, in a case where the structure is assembled while being sandwiched by the coolers from the outside, it is preferable that desired parallelism should be ensured between an upper surface of the fourth metal body 11 and the back surface side of the semiconductor device, i.e., the back surface of the second metal body 3. Otherwise, there occurs a larger gap between the coolers and the semiconductor device and this may deteriorate the thermal radiation when the coolers are externally attached to the semiconductor device.

Then, there may be a case where the fourth metal body 11 is formed thicker in advance and after molding the structure with mold resin 13, the upper surface of the fourth metal body 11 is ground away to thereby adjust the exposure thereof and the parallelism. In this case, also in order not to damage the second insulating layer 10 by grinding resistance, it is preferable that the fourth metal body 11 should be formed thicker than the second metal body 3.

Further, in order to achieve and maintain high parallelism in the upper and lower surfaces of the semiconductor device, it is preferable that the structure should be formed so that the metal bodies provided in the upper and lower directions of the semiconductor element 1 may have almost the same rigidity.

In contrast to this case, in the semiconductor device of the present invention, the thick first metal body 2 is formed on the back surface side of the semiconductor element 1 and further the thin second metal body 3 is formed thereon in the lower direction with the first insulating layer 4 sandwiched therebetween. On the other hand, the thin third metal body 9 is formed on the front surface side of the semiconductor element 1 and further the thick fourth metal body 11 is formed thereon in the upper direction with the second insulating layer 10 sandwiched therebetween.

In such a structure, the upper and lower structures which sandwich the semiconductor element 1 have almost the same rigidity on the whole, and this reduces the warp of the semiconductor device after molding. Therefore, it becomes easier to attach the structure to the coolers and the mechanical stress to be exerted on the semiconductor element 1 can be reduced.

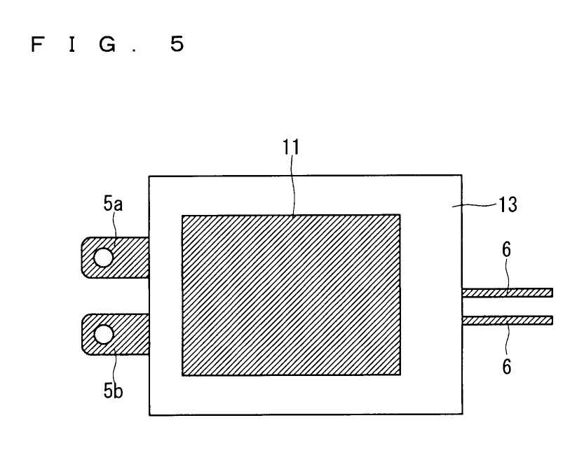

FIG. 5 is a plan view showing the semiconductor device, for explanation of the first preferred embodiment of the present invention. As shown in FIG. 5, the upper surface of the fourth metal body 11 is exposed from the mold resin 13 and the signal terminal 6 and the main terminals 5a and 5b are extended from side surfaces of the mold resin 13.

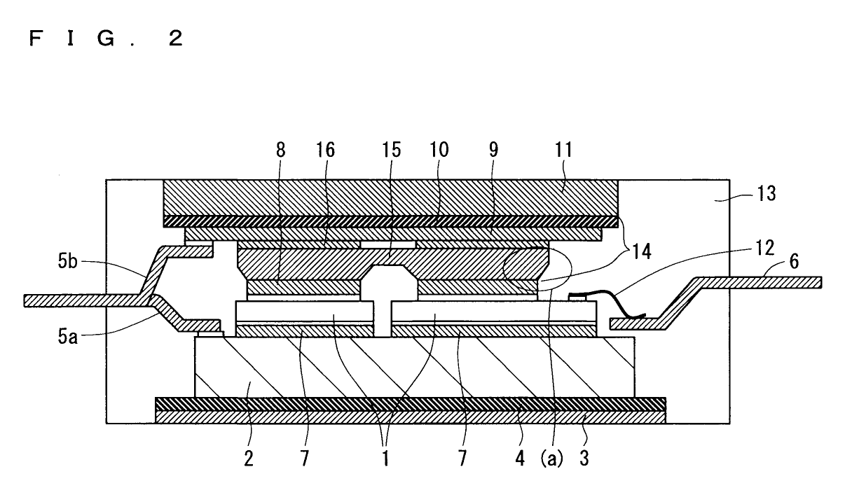

FIG. 2 is a schematic cross sections showing a variation of the semiconductor device in accordance with the first preferred embodiment. The constituent elements identical to those shown in FIG. 1 are represented by the same reference signs and detailed description thereon will be omitted.

In the present variation, a fifth metal body 15 is formed between the semiconductor element 1 and the third metal body 9 on the front surface side of the semiconductor element 1. The fifth metal body 15 is bonded to the third metal body 9 with, for example, a junction layer such as a solder or the like (a solder 16 in FIG. 2) interposed therebetween.

If an upper surface of the fifth metal body 15 is higher than the vertical level (height) which a loop of the bonding wire 12 reaches, preferably, the third metal body 9 and the bonding wire 12 do not interfere with each other. Therefore, it is preferable that the thickness of the fifth metal body 15 in the vertical direction should be large enough to satisfy this condition.

By providing the fifth metal body 15, since the heat is sufficiently diffused between the heat-generating semiconductor element 1 and the second insulating layer 10, the attained temperature in the second insulating layer 10 decreases. Therefore, it is possible to prevent delamination between the second insulating layer 10 and the third metal body 9 or between the second insulating layer 10 and the fourth metal body 11, which is caused by the temperature cycle. Further, it is also possible to prevent change in the quality of the second insulating layer 10 formed of an organic material or the like, due to the temperature.

Further, in FIG. 2, the fifth metal body 15 is provided with an inclined portion as indicated by (a) of FIG. 2 at an end of the metal body outside a portion which is connected with the solder 8. In other words, the fifth metal body 15 is broadened toward the upper direction. By forming the fifth metal body 15 in this manner, it is possible to further diffuse the heat while maintaining the breakdown voltage around the semiconductor element 1. Further, instead of the inclined shape as shown in FIG. 2, the fifth metal body 15 may be provided with, for example, a step-like shape so that the width of the fifth metal body 15 in the horizontal direction may increase toward the upper direction.

Further, a metal substrate 14 in which the second insulating layer 10, the third metal body 9, and the fifth metal body 15 are united in advance may be formed and provided inside the semiconductor device. By forming the metal substrate 14 in this manner, it is possible to reliably form the thick fourth metal body 11 above the second insulating layer 10 and thereby increase the industrial value.

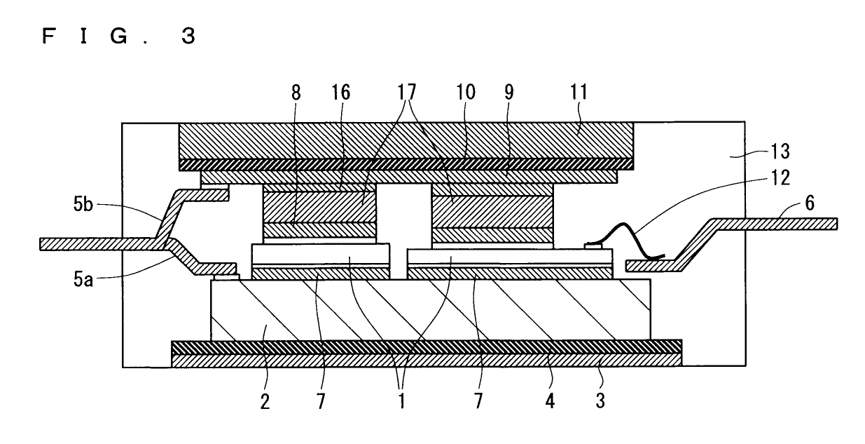

FIG. 3 shows a case where fifth metal bodies 17 are individually provided on the semiconductor elements, respectively. The constituent elements identical to those shown in FIG. 2 are represented by the same reference signs and detailed description thereon will be omitted.

In some cases, the semiconductor elements 1 have different thicknesses in the vertical direction depending on the types thereof. In such a case, by connecting the respective fifth metal bodies 17 with junction layers such as solders (solders 16 in FIG. 3) having different thicknesses so as to absorb the difference in the thickness, it is possible to appropriately assemble the structure even when, for example, the fifth metal bodies 17 having the same thickness are formed. Conversely, even when the solders 16 having the same thickness are used, by providing the fifth metal bodies 17 having different thicknesses correspondingly to the semiconductor elements 1, it is possible to appropriately assemble the structure.

Further, how to form the separate fifth metal bodies 17, specifically, whether the separate fifth metal bodies 17 are provided in a one-to-one correspondence with the semiconductor elements 1 or one metal body is provided for a plurality of semiconductor elements 1, or whether the combination of these manners is used or not, may be determined to obtain an appropriate structure in accordance with the circuit configuration.

Each of the separate fifth metal bodies 17 may be broadened toward the upper direction as show in FIG. 2, and a metal substrate in which the second insulating layer 10, the third metal body 9, and the fifth metal bodies 17 are united in advance may be formed.

<A-2. Manufacturing Method>

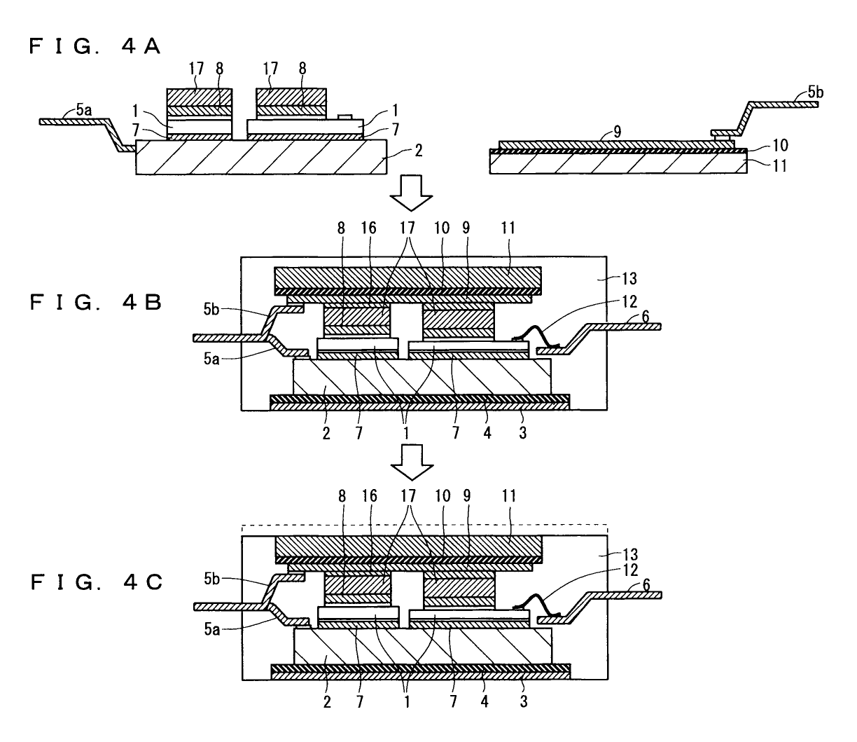

FIGS. 4A to 4C show a flowchart of manufacturing the semiconductor device shown in FIG. 3.

First, the semiconductor element 1 (chip) is provided on the first metal body 2 and bonded to each other. At that time, if the fifth metal bodies 17 are bonded at the same time, a process step can be omitted (FIG. 4A).

Further, the second insulating layer 10, the third metal body 9, and the fourth metal body 11 may be united by pressing or the like in advance, and the main terminal 5b may be soldered thereto as necessary.

After assembling these constituent elements, the elements are molded as shown in FIG. 4B. At that time, the layer of the mold resin 13 is also formed above the fourth metal body 11.

After that, the upper surface of the semiconductor device is grounded to a predetermined thickness (FIG. 4C). By grinding, it is possible to maintain excellent parallelism of the upper and lower surfaces of the semiconductor device. Therefore, there occurs no unnecessary gap when the structure is attached to the cooler and it is possible to achieve excellent heat radiation performance.

Since the insulating layer has low strength, by molding the structure in the state where the second insulating layer 10 which cannot be held by a mold is held by the fourth metal body 11 in advance, it is possible to achieve a double-sided insulating structure having insulating layers with excellent insulation properties.

Further, it is not necessary to expose the upper surface of the fourth metal body 11 in molding and also not necessary to perform complicated management or high-frequency maintenance for maintaining the mold with high precision, and it is therefore possible to reliably manufacture a semiconductor device with an upper surface thereof exposed in an excellent manner.

Further, the third metal body 9, the second insulating layer 10, and the fifth metal bodies 17 are integrally formed by pressing or the like, and after that, the semiconductor device is manufactured by assembling the structure. It is thereby possible to reliably bond the insulating layers and metal bodies.

<A-3. Effects>

In the preferred embodiment of the present invention, the semiconductor device comprises the semiconductor element 1, the first metal body 2 formed on the back surface of the semiconductor element 1, the first insulating layer 4 formed on the back surface of the first metal body 2, the second metal body 3 formed on the back surface of the first insulating layer 4, the third metal body 9 formed on the front surface of the semiconductor element 1, the second insulating layer 10 formed on the front surface of the third metal body 9, and the fourth metal body 11 formed on the front surface of the second insulating layer 10, and the second metal body 3 is thinner than the first metal body 2 and the fourth metal body 11 is thicker than the third metal body 9. Thus, by providing thin third metal body 9 on the front surface side of the semiconductor element 1, it is possible to reduce the stress to be exerted on the semiconductor element 1. Further, by providing the thick first metal body 2 on the back surface side of the semiconductor element 1, it is possible to achieve the low thermal resistance and increase the thermal radiation.

Even when there occurs an inclination in the first insulating layer 4 and the second insulating layer 10 due to the unsymmetrical pressure generated when the mold is brought into contact in molding, by grinding the thick fourth metal body 11 after the molding, the parallelism in the upper and lower surfaces can be adjusted. It is therefore possible to suppress deterioration in the heat radiation performance due to the partial contact.

Further in the preferred embodiment of the present invention, the semiconductor device further comprises the mold resin 13 which is so formed as to cover the semiconductor element 1, the first metal body 2, the second metal body 3, the third metal body 9, the fourth metal body 11, the first insulating layer 4, and the second insulating layer 10, and the back surface of the second metal body 3 is exposed from the mold resin 13 and the front surface of the fourth metal body 11 is exposed from the mold resin. It is thereby possible to increase the thermal radiation.

Since the fourth metal body 11 can be exposed even when the accuracy of the parallelism between the second metal body 3 and the fourth metal body 11 is not high, high productivity is achieved.

In the preferred embodiment of the present invention, in the semiconductor device, the third metal body 9, the second insulating layer 10, and the fourth metal body 11 are integrally formed as a laminate substrate. Therefore, molding can be performed in the state where the second insulating layer 10 which has low strength and cannot be held by a mold is held by the third metal body 9 and the fourth metal body 11 in advance, and it is thereby possible to achieve a double-sided insulating structure with excellent insulation properties.

In the preferred embodiment of the present invention, in the semiconductor device, the third metal body 9, the second insulating layer 10, and the fourth metal body 11 form a circuit board. Therefore, it becomes easier to supply it in molding, and it is thereby possible to reliably ensure the adhesion between the insulating layer and the metal bodies.

In the preferred embodiment of the present invention, in the semiconductor device, the semiconductor element 1 is formed of silicon carbide. Therefore, the semiconductor element having a synergistically high breakdown voltage can be used, and it is thereby possible to provide a semiconductor device having a high breakdown voltage.

In the preferred embodiment of the present invention, the semiconductor device further comprises the fifth metal body 15 or the fifth metal bodies 17 formed between the semiconductor element 1 and the third metal body 9. The heat is thereby diffused sufficiently between the heat-generating semiconductor element 1 and the second insulating layer 10. Therefore, the attained temperature in the second insulating layer 10 decreases and it is possible to prevent change in the quality and delamination due to the temperature.

In the preferred embodiment of the present invention, in the semiconductor device, the fifth metal body 15 or each of the fifth metal bodies 17 is broadened toward the front surface. It is thereby possible to further diffuse the heat and increase the thermal radiation while maintaining the breakdown voltage around the semiconductor element 1.

In the preferred embodiment of the present invention, in the semiconductor device, the third metal body 9, the second insulating layer 10, and the fifth metal body 15 are integrally formed as the metal substrate 14. Therefore, molding can be performed in the state where the second insulating layer 10 which has low strength and cannot be held by a mold is held by the third metal body 9 and the fourth metal body 11 in advance, and it is thereby possible to achieve a double-sided insulating structure with excellent insulation properties.

In the preferred embodiment of the present invention, the semiconductor device comprises a plurality of semiconductor elements 1 and a plurality of fifth metal bodies 17 corresponding to the semiconductor elements 1, and the third metal body 9 is formed across the respective front surfaces of the plurality of fifth metal bodies 17. Therefore, it is possible to incorporate a variety of variations of circuit configurations into the semiconductor device by combinations of the metal bodies and the insulating layers.

In the preferred embodiment of the present invention, the materials of the constituent elements, the conditions, and the like have been described, but these are illustrative and not restrictive.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor element;
a first metal body formed on a back surface of said semiconductor element;
a first insulating layer formed on a back surface of said first metal body;
a second metal body formed on a back surface of said first insulating layer;
a third metal body formed on a front surface of said semiconductor element;
a second insulating layer formed on a front surface of said third metal body; and
a fourth metal body formed on a front surface of said second insulating layer,
wherein said second metal body is thinner than said first metal body, and
said fourth metal body is thicker than said third metal body.

2. The semiconductor device according to claim 1, further comprising:
a mold resin which is so formed as to cover said semiconductor element, said first to fourth metal bodies, and said first and second insulating layers,
wherein said second metal body has a back surface which is exposed from said mold resin, and
said fourth metal body has a front surface which is exposed from said mold resin.

3. The semiconductor device according to claim 1, wherein
said third metal body, said second insulating layer, and said fourth metal body are integrally formed as a laminate substrate.

4. The semiconductor device according to claim 1, wherein
said third metal body, said second insulating layer, and said fourth metal body form a circuit board.

5. The semiconductor device according to claim 1, wherein
said semiconductor element is formed mainly of silicon carbide.

6. The semiconductor device according to claim 1, further comprising:
a fifth metal body formed between said semiconductor element and said third metal body.

7. The semiconductor device according to claim 6, wherein
said fifth metal body is broadened toward said front surface.

8. The semiconductor device according to claim 6, wherein
said third metal body, said second insulating layer, and said fifth metal body are integrally formed as a metal substrate.

9. The semiconductor device according to claim 6, comprising:
a plurality of said semiconductor elements; and
a plurality of said fifth metal bodies corresponding to said semiconductor elements,
wherein said third metal body is formed across respective front surfaces of said plurality of fifth metal bodies.

10. A method of manufacturing a semiconductor device, comprising the steps of:
(a) forming a first metal body on a back surface of a semiconductor element;
(b) forming a first insulating layer on a back surface of said first metal body;
(c) forming a second metal body on a back surface of said first insulating layer;
(d) forming a third metal body on a front surface of said semiconductor element;
(e) forming a second insulating layer on a front surface of said third metal body; and
(f) forming a fourth metal body formed on a front surface of said second insulating layer,
wherein said second metal body which is thinner than said first metal body is formed in said step (c), and
said fourth metal body which is thicker than said third metal body is formed in said step (f).

11. The method of manufacturing a semiconductor device according to claim 10, wherein
said third metal body, said second insulating layer, and said fourth metal body are integrally formed as a metal substrate on said front surface of said semiconductor element in said steps (d), (e), and (f).

12. The method of manufacturing a semiconductor device according to claim 10, further comprising the steps of:
(g) so forming a mold resin as to cover said semiconductor element, said first to fourth metal bodies, and said first and second insulating layers; and
(h) exposing at least a front surface of said fourth metal body from said mold resin.

13. The method of manufacturing a semiconductor device according to claim 10, further comprising the step of:
(i) forming a fifth metal body on said front surface of said semiconductor element before said step (d),
wherein said third metal body is formed on a front surface of said fifth metal body in said step (d).
